(19) United States
(12) Patent Application Publication
(10) Pub. No.: US 2007/0197039 A1
(43) Pub. Date: Aug. 23, 2007

(54) ANISOTROPIC ETCHING METHOD

(75) Inventor: Michel Puech, Metz-Tessy (FR)

Correspondence Address: SUGHRUE MION, PLLC, 2100 PENNSYLVANIA AVENUE, N.W., SUITE 800, WASHINGTON, DC, 20037, US

(73) Assignee: Alcatel Lucent, Paris (FR)

(21) Appl. No.: 11/669,028

(22) Filed: Jan. 30, 2007

(30) Foreign Application Priority Data
Feb. 1, 2006 (FR) 0650357

(51) Int. Cl. H01L 21/306; C23F 1/00

(52) U.S. Cl. 438/706; 438/710; 438/719; 156/345.33; 156/345.51

(57) ABSTRACT

The present invention consists in a method for anisotropically etching a silicon substrate at very low temperature using a high-density fluorinated gas plasma, characterized in that the plasma is formed from a gas mixture comprising an etching gas containing fluorine, a passivating gas containing oxygen and a reaction gas comprising chlorine, and in which method the respective ratios of the flowrate of the passivating gas and the flowrate of the reaction gas to the flowrate of the etching gas are less than 0.15 by volume. The etching gas containing fluorine is preferably sulfur hexafluoride SF₆, the passivating gas containing oxygen is preferably chosen from oxygen O₂, ozone O₃ and sulfur dioxide SO₂, and the reaction gas comprising chlorine is preferably silicon tetrachloride SiCl₄.

### CROSS-REFERENCE TO RELATED APPLICATIONS

This application is based on French Patent Application No. 0650357 filed Feb. 1, 2006, the disclosure of which is hereby incorporated by reference thereto in its entirety, and the priority of which is hereby claimed under 35 U.S.C. §119.

### BACKGROUND OF THE INVENTION

1. Field of the Invention

The present invention relates to a method of etching anisotropically at very low temperature using a high-density fluorinated gas plasma to produce microreliefs on the surface of semiconductor substrates, in particular silicon substrates for the production of semiconductor components and microsystems known as micro-electro-mechanical systems (MEMS) and micro-opto-electro-mechanical systems (MOEMS).

2. Description of the Prior Art

These Microsystems necessitate deep and highly anisotropic etching with high selectivity and high rates of attack. Techniques based on non-toxic, non-corrosive and simple chemistries are preferable.

A fluorine-based etching gas plasma is conventionally used to generate a maximum of ions and atoms of fluorine enabling high silicon attack speeds. The fluorine ions and atoms are known to react spontaneously and exothermically with silicon to bring about isotropic attack. However, for greater accuracy, the aim is to obtain a pattern the walls whereof are as vertical as possible. Anisotropic etching by means of a fluorinated gas therefore necessitates protection of the flanks of the etched pattern by depositing a passivating layer in order to promote attack in the bottom of the pattern whilst protecting the sides. Gases based on halogens other than fluorine, such as chlorine, bromine or iodine, enable anisotropic etching of silicon, but at the cost of a very slow rate of attack, and so are rarely used in practice. The problem is therefore to make etching more anisotropic without increasing the duration of the etching operation. Alternative solutions have been proposed.

A first method called the “pulsed method” is proposed and described in particular in the document U.S. Pat. No. 5,501,893, according to which the phases of etching the substrate and depositing the passivating layer alternate. During a first step an etching gas, for example an SF₆ and argon mixture, is directed onto the substrate, followed during a second step by a passivating gas, for example a C₄F₈ or CHF₃ and argon mixture, which deposits a layer of polymer onto the walls of the etched pattern.

This technique has a number of drawbacks, however, such as that of being “dirty” and highly sensitive to the condition of the walls of the reactor. On the one hand, the time necessary to remove the film in the bottom of the trench induces a process time that is not used to attack the silicon, which entails an increase in the overall duration of the step of etching the substrate. Likewise selectivity is reduced by the projection of energetic ions that also attack the etching mask. On the other hand, the use of a fluorocarbon gas such as C₄F₈ is costly. Finally, the alternation of the etching and deposition phases generates undulations on the etched flanks.

The other method that has been proposed is that known as the “continuous method” which consists in adding to the etching gas a gas for promoting the formation of polymers so as to deposit a layer of polymer over the whole of the surface of the substrate bared by the etching process. The passivating gas is usually a fluorocarbon gas and a layer of CₓF_{y} or COₓF_{y} is then deposited on the surface of the substrate. After removal of the protective polymer film in the bottom of the cavity by vertical bombardment by the plasma, the bottom of the cavity is attacked selectively. The passivation therefore prevents the ionized etching gas plasma attacking the lateral walls of the cavity. Accordingly, despite the isotropic nature of the attack on the silicon by an etching gas plasma such as a fluorinated gas plasma, the silicon is etched quasi-anisotropically.

This technique is illustrated in particular by the document WO-99/67 817 which describes a method for deep etching of silicon that uses a combination of reactive gases comprising a gas containing fluorine but not silicon (FC), a gas containing silicon, and preferably also fluorine (SC), and oxygen (O₂) in fixed proportions on which the selectivity depends. A smaller quantity of another halogenated gas may be added. If the gas SC contains silicon and fluorine, the following ratios by volume apply: FC/SC=25 to 0.1 and O₂/FC=10 to 0.1. This gas mixture is a mixture of SF₆(FC)+SiF₄(SC)+O₂, for example. Because the reaction is exothermic, the substrate must be cooled to maintain its temperature from 70° C. to 140° C.

Another method is described in the document US-2004/0,097,090 which proposes a method using a mixture of a fluorinated gas containing carbon or sulfur, a fluorinated gas containing silicon and oxygen, for example an SF₆/SiF₄/O₂ mixture. The ratio of the concentration of the oxygen to that of the fluorinated gas containing carbon or sulfur is from 0.2 to 0.8. The concentration of the fluorinated gas containing silicon represents at least 10% of the total mixture. To etch at least 20 μm, the flowrates of the gases constituting the mixture are in the following ratio: fluorinated gas containing carbon or sulfur/oxygen/fluorinated gas containing silicon 0.8 to 2.4/0.16 to 0.96/1. During the etching operation the temperature of the sample-carrier is from −30° C. to +20° C.

However, controlling the effect of each gas necessitates precise control of the process parameters, such as the partial pressure of each gas, the power of the plasma source and/or the bias of the substrate, for example. Moreover, this method is highly sensitive to the state of the walls of the processing chamber. The pollution resulting from the presence of a gas forming a polymer necessitates a cleaning operation after the etching operation, which slows down the process.

A different approach is described in the paper “Low temperature etching of Si and PR in high density plasma” by M. PUECH and Ph. MAQUIN (Appl. Surf. Sc., 100/101, (1996), 579-582). This deep (>50 μm) etching method, called the “cryogenic method”, combines adding a small quantity of oxygen to a fluorinated etching gas, such as SF₆, with reducing the temperature of the surface of the substrate to around −100° C. Maintaining the surface of the substrate at a low temperature is essential for obtaining anisotropic etching by contributing to the formation of a passivating layer, of the silico-oxygen SiO and/or silico-fluorine SiF type, or a thin layer of SiOₓF that protects the vertical walls of the etched pattern. Silicon is always attacked isotropically by SF₆ at a temperature of −100° C. and in the absence of oxygen. Thus with a very low substrate temperature, it is possible to obtain anisotropic profiles even with small quantities of oxygenated gas flow. The formation of “black silicon” is observed if the proportion of oxygen is too high. Black silicon is a deterioration of the bottom of the pattern caused by excessive passivation of these surfaces and consisting of fines dendrites and porosities, instead of the usual smooth pattern bottom. The formation of black silicon blocks vertical etching of the silicon randomly and must therefore be avoided.

The authors have observed that it is impossible to achieve anisotropic attack at a temperature of +10° C. even if the proportion of oxygen added is increased. In fact, to retain the same anisotropic quality, room temperature etching methods are subject to volumetric gas ratio conditions that are much higher, entailing in particular strong flows of oxygenated gases. The oxygenated gas plasma induces a loss of selectivity because of its well-known capacities for etching the resin mask. To retain acceptable selectivity, the application of continuous methods of room temperature anisotropic etching must then be limited to masks of the “hard mask” type based on inorganic materials (WO 99/67817).

The drawback of this method of anisotropic etching at very low temperature is that the range of regulation of the process parameters, in particular the temperature, the partial pressure of the gases and the substrate bias voltage, is too narrow. For example, the method necessitates the temperature of the surface of the substrate to be controlled to within 0.5° C., which is difficult to achieve. If the temperature is too low, a switch to the black silicon state may be observed. Other process parameters such as the quantity of oxygen introduced into the gas mixture or the bombardment energy can also produce black silicon if they are not well optimized. If the partial pressure of oxygenated gas varies by plus or minus 2% of the initial flowrate, the etching regime can switch either to underpassivation or to overpassivation (black silicon).

If a parameter is not well optimized, the process is no longer perfectly anisotropic. The silicon may become depassivated at certain places, in particular on the upper profile portions that are particularly sensitive because they are exposed to ionic bombardment by the plasma for longest. Ions that do not have a perfectly vertical trajectory may shift or break the SiOₓF_{y} bonds and “holes” may appear, creating defects. These defects are larger or smaller according to the size of the patterns.

Finally, the slightest discrepancy in the regulation of the temperature of the substrate can lead to one or the other of the above states, the effect of which will be to produce profiles that will not be perfectly anisotropic. The substrate-carrier temperature is uniform to better than ±1° C., and no further mechanical design improvements are now expected liable to improve this uniformity further. Moreover, even if the temperature of the substrate-carrier is perfectly regulated, given possible surface state variations from one substrate to another (the rear face of the substrate may or may not include a thicker or thinner oxide layer), and the geometry of the samples, the surface temperature of the substrate may undergo variations that can reach 1° C.

### SUMMARY OF THE INVENTION

An object of the present invention is to propose a method for anisotropically etching silicon at very low temperature that does not have the drawbacks of the known method.

In particular, the proposed method allows for a wider window of variation in process parameters, in particular the temperature of the surface of the substrate, at the same time as preserving the anisotropic nature and the quality of the etching.

The present invention consists in a method for anisotropically etching silicon at very low temperature using a high-density fluorinated gas plasma, wherein the plasma is formed from a gas mixture comprising (a) an etching gas containing fluorine, (b) a passivating gas containing oxygen and (c) a reaction gas comprising chlorine, in which method the respective ratios of the flowrate of the passivating gas and the flowrate of the reaction gas to the flowrate of the etching gas are less than 0.15 by volume.

According to a first aspect of the invention, the respective ratios of the flowrate of the passivating gas and the flowrate of the reaction gas to the flowrate of the etching gas are from 0.01 to 0.10 by volume.

The ratio of the flowrate of the passivating gas to the flowrate of the etching gas is preferably from 0.02 to 0.08 by volume.

The ratio of the flowrate of the reaction gas to the flowrate of the etching gas is preferably from 0.01 to 0.08 by volume.

According to a second aspect of the invention, the flowrate of introduction of the etching gas is preferably from 0.20 l/min to 0.40 l/min, i.e. 200 sccm to 400 sccm (sccm: standard cubic centimeters per minute) The flowrate of introduction of the passivating gas and the reaction gas is preferably from 0.001 l/min to 0.030 l/min, i.e. 1 sccm to 30 sccm.

The flowrate of introduction of the passivating gas is preferably from 0.010 l/min to 0.030 l/min, i.e. 10 sccm to 30 sccm.

The flowrate of introduction of the reaction gas is preferably from 0.005 l/min to 0.015 l/min, i.e. 5 sccm to 15 sccm.

According to a third aspect of the invention, the temperature of the surface of the substrate is lower than −70° C. The temperature of the surface of the substrate is preferably from −80° C. to −110° C.

According to a fourth aspect of the invention, the etching gas containing fluorine is sulfur hexafluoride SF₆.

The reaction gas may also be a passivating gas. The reaction gas comprising chlorine is preferably silicon tetrachloride SiCl₄.

The passivating gas containing oxygen is preferably selected from oxygen O₂, ozone O₃ and sulfur dioxide SO₂. A gas is advantageously used having stronger oxidizing properties than oxygen O₂, such as ozone O₃ and sulfur dioxide SO₂, for example.

The invention also consists in a device for implementing the above method of anisotropically etching a silicon substrate at very low temperatures using a high-density fluorinated gas plasma. This device comprises:

a vacuum process chamber,

a source for generating a plasma by inductive coupling,

a substrate-carrier provided with means for cooling the substrate that it carries,

means for monitoring and managing the temperature of the substrate, and

at least three variable flowrate gas inlet lines for respectively introducing an etching gas containing fluorine, a passivating gas containing oxygen and a reaction gas comprising chlorine.

According to one particular embodiment of the invention, the reaction gas is introduced at the outlet of the tube of the plasma source in the direction of the process chamber. The reaction gas is preferably introduced into the process chamber.

In this case the device includes reaction gas injection means comprising a torus pierced with a plurality of orifices.

The method of the invention aims to strengthen or to ensure the integrity of the passivating layer that protects the etched flanks throughout the etching step in order to make it less sensitive to variations in the process parameters. In fact this layer is very fragile and in particular gives rise to irreversible defects produced during etching by the prior art methods. The passivating layer produced by the method according to the present invention has the particular feature of sublimating easily when the temperature rises above −70° C. By avoiding the presence of the C, CₓF_{y} or PTFE type pollutants of the prior art methods, the passivating layer gives the method the advantage of being a very clean etching method. The walls of the chambers remain clean and the surfaces of the substrates are therefore always clean. This is an important advantage from the industrial point of view because the steps of cleaning these chambers, mechanically or by means of a plasma, are no longer necessary. This increases the availability of these chambers and it is no longer necessary to provide a dedicated heating system for cleaning purposes.

Other advantages flow from this method. Adjustment of the process parameters is simplified and it therefore becomes possible to widen the range of temperatures of the surface of the substrate. All of the operating time is devoted to etching, which means that the etching rates of the process are inherently high. For the same type of pattern to be etched, it has been shown that an etching rate of 2.92 μm/min can be achieved by the method according to the invention, compared to the 1.45 μm/min obtained with a prior art method known as the “pulsed method”.

Patterns with very high form factors necessitate control of anisotropy over longer time periods than micronic etching methods over depths that may reach several hundred microns. The very low temperature etching method according to the invention avoids degrading the resin of the etching mask, which is exposed to the plasma for longer.

Other features and advantages of the present invention will become apparent in the course of the following description of embodiments of the invention given by way of illustrative and nonlimiting example and from the appended drawings.

### BRIEF DESCRIPTION OF THE DRAWINGS

FIG. 1 represents a device for implementing the method according to the present invention.

FIG. 2 represents a variant of the FIG. 1 device.

### DETAILED DESCRIPTION OF THE PREFERRED EMBODIMENTS

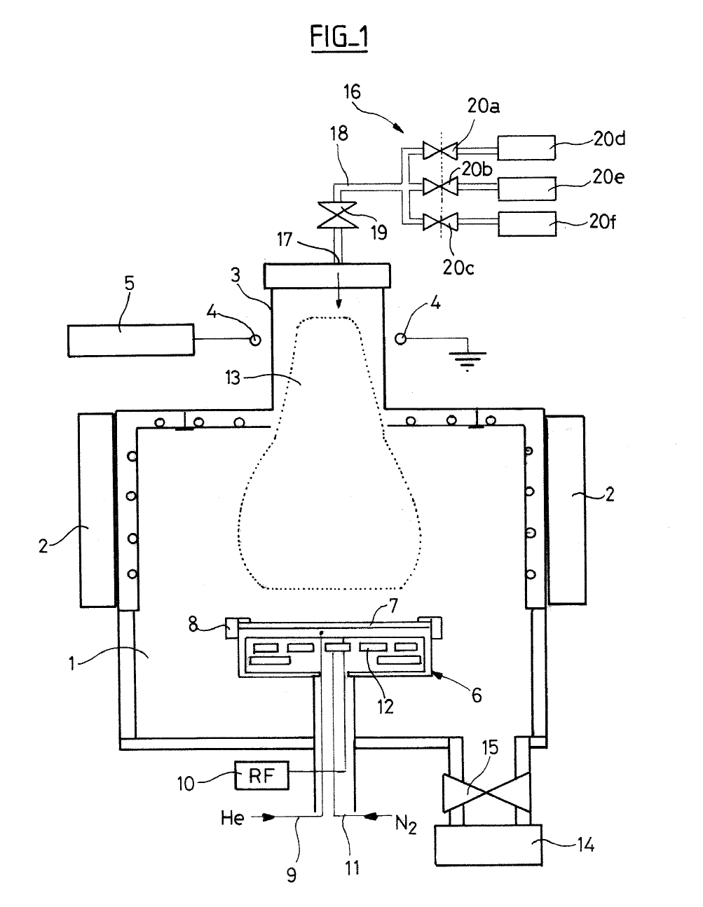

The device represented in FIG. 1 is a plasma etching machine that comprises a process chamber 1 surrounded by permanent magnets 2 in a multipolar arrangement to reduce electron loss at the walls of the chamber. The chamber 1 communicates with a plasma source the dielectric material tube 3 whereof, in which the plasma is formed, is surrounded by a coupling electrode 4 fed with radio-frequency (RF) alternating current by an RF generator 5 supplying an RF (13.56 MHz) power P from 500 W to 2000 W.

The chamber 1 contains a substrate-carrier 6. A substrate 7 to be etched approximately 100 mm thick is fixed to the substrate-carrier 6 by mechanical or electrostatic means, here mechanically by means of a ring 8, for example. The substrate 7 is separated from the substrate-carrier 6 by a film 9 of helium. A bias voltage U from 20 V to 60 V, preferably of the order of 50 V, is applied to the substrate 7 by means of an RF (13.56 MHz) or low-frequency (50-500 kHz) generator 10. The substrate 7 is cooled from its rear face by circulating a cooling liquid 11, such as liquid nitrogen (N₂), in passages 12 formed in the substrate-carrier 6. Such a system enables thermal control of a substrate in a temperature range that can extend from −140° C. to +20° C. The substrate 7 is held at a temperature T that is preferably from −100° C. to −80° C.

The coupling electrode 4 excites the gases in the tube 3 to produce a plasma 13 that is then moved toward the interior of the reaction chamber 1, in the direction of the substrate-carrier 6.

The chamber 1 is connected to a secondary pumping set comprising a turbomolecular pump 14 via a system 15 for regulating the pressure in the chamber. The working pressure in the process chamber 1 is stabilized and regulated by the system 15 to a value from 2 Pa to 10 Pa. An inlet and flowrate control system 16 admits various gases, for example SF₆, O₂ and SiCl₄ here. The passivating gas, here O₂, may be introduced into the chamber 1 as the process proceeds in accordance with a ramp type set point. Here, the flow of O₂ may be from 1 sccm to 30 sccm for a flow of SF₆ of 240 sccm. The quantity of SiCl₄ that is introduced may be adjusted as a function of the geometry of the pattern to be etched.

The gas injection system 16 includes a gas inlet 17 into the process chamber 1, preferably on the upstream side of the plasma generation zone, the gas inlet 17 being connected by a pipe 18, an isolating valve 19 and gas flowrate control valves 20a, 20b and 20c to an etching gas supply 20d, a passivating gas supply 20e and a reaction gas supply 20f. The etching gas supply 20d and the etching gas flowrate control means 20a, such as a solenoid valve, control the introduction of etching gas into the plasma source via the end of the tube 3 when the isolating valve 19 is opened. Similarly, the passivating gas supply 20e and the passivating gas flowrate control means 20b, such as a solenoid valve, control the introduction of passivating gas into the plasma source via the end of the tube 3 when the isolating valve 19 is opened. The reaction gas supply 20f and the reaction flowrate control means 20c, such as a solenoid valve, control the introduction of reaction gas into the plasma source 4 via the end of the tube 3 when the isolating valve 19 is opened.

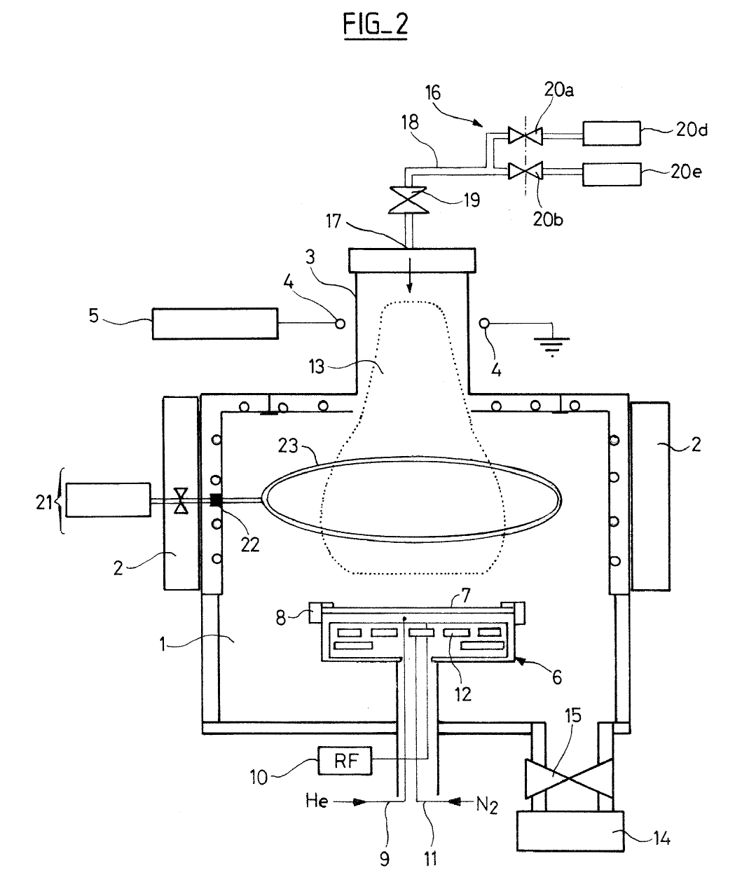

Alternatively, it is highly advantageous if the reaction gas is injected into a “post-discharge” zone that is situated after the plasma source and directly in the process chamber 1, as represented in FIG. 2. In this way the reaction gas is dissociated as close as possible to the substrate 7, which prevents the fragmented gas from recombining before reaching the surface of the substrate 7 and thus avoids contamination of the substrate 7. Dedicated reaction gas injection means 21 may be provided in the chamber. These means may comprise an orifice 22 in the wall of the chamber 1. The reaction gas injection means 21 preferably include a torus 23 with a plurality of orifices on its inside perimeter.

1. A method for anisotropically etching a silicon substrate at very low temperature using a high-density fluorinated gas plasma formed from a gas mixture comprising an etching gas containing fluorine, a passivating gas containing oxygen and a reaction gas comprising chlorine, in which method the respective ratios of the flowrate of the passivating gas and the flowrate of the reaction gas to the flowrate of the etching gas are less than 0.15 by volume.

2. The method according to claim 1, wherein the respective ratios of the flowrate of the passivating gas and the flowrate of the reaction gas to the flowrate of the etching gas are from 0.01 to 0.10 by volume.

3. The method according to claim 2, wherein the ratio of the flowrate of the passivating gas to the flowrate of the etching gas is from 0.02 to 0.08 by volume.

4. The method according to claim 2, wherein the ratio of the flowrate of the reaction gas to the flowrate of the etching gas is from 0.01 to 0.08 by volume.

5. The method according to claim 1, wherein the flowrate of introduction of the etching gas is from 0.20 l/min to 0.40 l/min.

6. The method according to claim 1, wherein the flowrate of introduction of the passivating gas and the reaction gas is from 0.001 l/min to 0.030 l/min.

7. The method according to claim 6, wherein the flowrate of introduction of the passivating gas is from 0.010 l/min to 0.030 l/min.

8. The method according to claim 6, wherein the flowrate of introduction of the reaction gas is from 0.005 l/min to 0.015 l/min.

9. The method according to claim 1, wherein the temperature of the surface of the substrate is lower than −70° C.

10. The method according to claim 9, wherein the temperature of the surface of the substrate is from −80° C. to −110° C.

11. The method according to claim 1, wherein the etching gas containing fluorine is sulfur hexafluoride.

12. The method according to claim 1, wherein the passivating gas containing oxygen is chosen from oxygen, ozone and sulfur dioxide.

13. The method according to claim 1, wherein the reaction gas comprising chlorine is silicon tetrachloride.

14. A device for implementing a method according to claim 1 of anisotropically etching a silicon substrate at very low temperatures using a high-density fluorinated gas plasma, comprising:
a vacuum process chamber,
a source for generating a plasma by inductive coupling,
at least three variable flowrate gas inlet lines for respectively introducing an etching gas containing fluorine, a passivating gas containing oxygen and a reaction gas comprising chlorine,
a substrate-carrier provided with means for cooling the substrate that it carries, and
means for monitoring and managing the temperature of the substrate.

15. The device according to claim 14 wherein the reaction gas is introduced at the outlet of the tube of the plasma source in the direction of the process chamber.

16. The device according to claim 14 wherein the reaction gas is introduced into the process chamber.

17. The device according to claim 15, which includes reaction gas injection means comprising a torus pierced with a plurality of orifices.
